(19) United States
(12) Patent Application Publication
(10) Pub. No.: US 2006/0261489 A1
(43) Pub. Date: Nov. 23, 2006

(54) Semiconductor memory card and method of fabricating the same

(76) Inventors: Yasuo Takemoto, Yokohama-shi (JP); Naohisa Okumura, Yokohama-shi (JP); Taku Nishiyama, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/437,780

(22) Filed: May 22, 2006

(30) Foreign Application Priority Data
May 23, 2005 (JP) 2005-149537
Apr. 28, 2006 (JP) 2006-126838

(51) Int. Cl. H01L 23/48

(52) U.S. Cl. 257/774

(57) ABSTRACT

A plurality of external connection terminals are formed on one surface of a printed board. Solder resist is coated on the other surface of the printed board so as to have an opening therein in at least part of an outer periphery of the board. A memory chip is mounted on the other surface of the board. A molding resin is provided which composes a package of a semiconductor memory card by sealing the other surface side of the board so as to cover the solder resist and the memory chip.

### CROSS-REFERENCE TO RELATED APPLICATIONS

This application is based upon and claims the benefit of priority from prior Japanese Patent Applications No. 2005-149537, filed May 23, 2005; and No. 2006-126838, filed Apr. 28, 2006, the entire contents of both of which are incorporated herein by reference.

### BACKGROUND OF THE INVENTION

1. Field of the Invention

The present invention relates to a semiconductor memory card in which a memory chip is mounted on a wiring board and a chip-mounted surface is sealed with a resin, whereby a package is composed.

2. Description of the Related Art

In recent years, in various portable electronic apparatuses such as personal computers (PCs), personal digital assistants (PDAs), digital cameras, and mobile phones, a semiconductor memory card which is one of removal storage devices has been used in many applications. For a semiconductor memory card, attention is being given to a PC card and a small SD card (TM). Furthermore, recently, a semiconductor memory card which is further miniaturized by forming external connection terminals on one surface of a wiring board, mounting a memory chip and a controller chip on the other surface of the wiring board, and sealing a chip-mounted surface with a molding resin to thereby compose a package, has been put into practical use. In such a further miniaturized semiconductor memory card, the side surfaces of the wiring board are exposed to the external appearance of a product. In addition to the external connection terminals, numbers of wiring lines are formed on both surfaces of the wiring board. In order to prevent a short-circuit trouble occurring between the wiring lines, a protective film called solder resist is coated and formed on the board. A molding resin material that composes a package is formed to cover the solder resist coated on one surface of the wiring board.

In a conventional semiconductor memory card, substantially the entire surface of a wiring board including an outer periphery where side surfaces are exposed is coated with solder resist. At the outer periphery of the card, the solder resist is closely adhered to a molding resin. However, since the solder resist and the molding resin are in contact with each other at their smooth surfaces, the adhesion strength is not so high. Hence, while an outer shape is processed, the wiring board and the molding resin are peeled off from each other and a so-called opening is provided at the side surfaces of the board, resulting in a defect.

Jpn. Pat. Appln. KOKAI Publication No. 2000-124344 discloses a semiconductor apparatus configured as follows. Opening portions are provided in a solder resist film on wiring lines on a backside of a chip mounting board and pad regions exposed from the opening portions function as external connection terminals. Furthermore, a sealing resin is filled in a sealing through-hole provided in the chip mounting board, and the bonding force between the sealing resin and the chip mounting board is increased by an anchor effect.

### BRIEF SUMMARY OF THE INVENTION

According to one aspect of the present invention, there is provided a semiconductor memory card which is usable mounted on a host apparatus, the semiconductor memory card comprising: a wiring board having a first surface and a second surface which face each other, and having a plurality of external connection terminals and a plurality of wiring lines formed on the first surface; a protective film formed on the second surface of the wiring board and having an opening in at least part of an outer periphery of the wiring board; a memory chip mounted on the second surface of the wiring board; and a resin film which composes a package of the semiconductor memory card by sealing a side of the second surface of the wiring board to cover the protective film and the memory chip.

### BRIEF DESCRIPTION OF THE SEVERAL VIEWS OF THE DRAWING

FIG. 1 is a cross-sectional view of a semiconductor memory card according to a first embodiment of the present invention;

FIG. 2 is a plan view of a chip-mounted surface side of a board of FIG. 1;

FIG. 3 is a plan view showing a part of a process of fabricating the semiconductor memory card according to the first embodiment;

FIG. 4 is a plan view of a surface opposite to the chip-mounted surface of the board of FIG. 1;

FIG. 5 is a plan view showing a state of connection between a chip mounted on the chip-mounted surface of the board of FIG. 1 and electrode pads on the board;

FIG. 6 is a plan view showing a specific example of the electrode pads and a wiring pattern formed on the chip-mounted surface of the board of FIG. 1;

FIG. 7 is a plan view showing a specific example of a wiring pattern formed on a chip unmounted surface of the board of FIG. 1;

FIG. 8 is a plan view of a board having a plating feeder line;

FIGS. 9A to 9I are cross-sectional views showing, in order of steps, a method of fabricating a semiconductor memory card, according to a second embodiment of the present invention;

FIG. 10 is a plan view showing an example of wiring lines on a semiconductor chip unmounted surface of the semiconductor memory card fabricated by the method according to the second embodiment;

FIG. 11 is a partial cross-sectional view of the semiconductor memory card fabricated by the method according to the second embodiment; and

FIG. 12 is a plan view of a board for use in a semiconductor memory card according to a third embodiment of the present invention.

### DETAILED DESCRIPTION OF THE INVENTION

The present invention will be described below by embodiments with reference to the drawings.

FIG. 1 is a cross-sectional view of a semiconductor memory card according to a first embodiment of the present invention. In the drawing, reference numeral 11 denotes an insulation board composed of, for example, an epoxy resin or a glass epoxy resin. The board 11 has one and other surfaces facing each other. A conductive material pattern, such as a plurality of external connection terminals and wiring lines, is formed on both surfaces of the board 11, whereby a wiring board is composed. FIG. 1 shows a state in which a plurality of wiring lines 12 and a plurality of electrode pads 13 are formed on the one surface of the board 11. Solder resist 14 is coated on the entire other surface of the board 11 which is a side where a memory chip is not mounted. Solder resist 14 is coated on the one surface of the board 11 which is a side where the memory chip is mounted, except where part of an outer periphery of the board 11 and the electrode pads 13 are present. Regions of the outer periphery of the board 11 that are not coated with the solder resist 14 are indicated by openings 15. Furthermore, a memory chip 17 is mounted on the one surface of the board 11 by using an insulating adhesive sheet 16. Normally, a controller chip that controls the operation of the memory chip 17 is stacked and mounted on the memory chip 17, but the description thereof is omitted in FIG. 1.

A plurality of electrode pads 18 are formed on the memory chip 17. The electrode pads 18 on the memory chip 17 and the electrode pads 13 formed on the board 11 are electrically connected to one another by metal wires 19. Further, a molding resin 20 that composes a package is formed on the surface side of the board 11 on which the chip 17 is mounted.

During a molding process of forming the molding resin 20, the molding resin 20 flows into the openings 15 that are not coated with the solder resist 14 so as to be filled in the openings 15, and thus, the board 11 and the molding resin 20 come into direct contact with each other in the part of the outer periphery of the board.

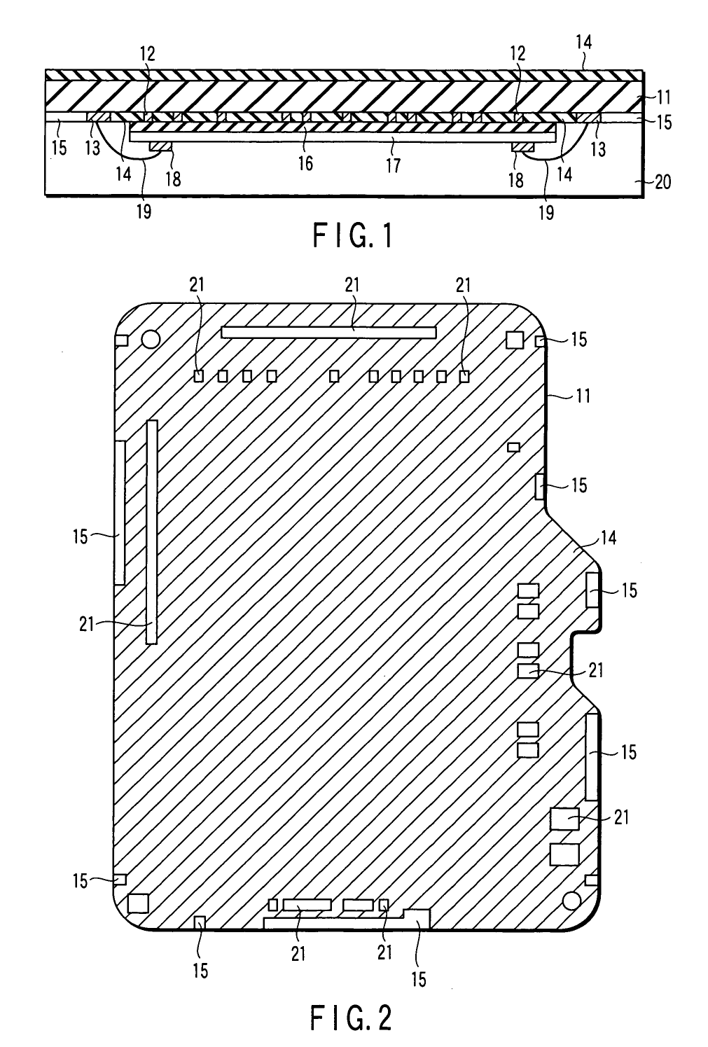

FIG. 2 is a plan view of the chip-mounted surface side of the board 11 of FIG. 1. In FIG. 2, a region coated with the solder resist 14 is cross-hatched. Portions that are not coated with the solder resist 14 include the openings 15 provided in part of the outer periphery of the board 11; the electrode pads 13 on the board 11 that are connected to the electrode pads 18 on the memory chip 17; and openings 21 that allow, for example, electrode pads used to connect components other than the memory chip 17, such as chip capacitors and chip resistors, to the electrode pads on the board 11, to be exposed therefrom.

In the semiconductor memory card of the first embodiment, the openings 15 that are not coated with the solder resist 14 are provided in part of the outer periphery of the board 11. The molding resin 20 flows into the openings 15, and accordingly, the board 11 comes into direct contact with the molding resin 20 in the part of the outer periphery of the board. As a result, by an anchor effect due to projection and depression formed by the portion coated with the solder resist 14 and the portion not coated with the solder resist 14, the adhesion force between the board 11 and the molding resin 20 is increased.

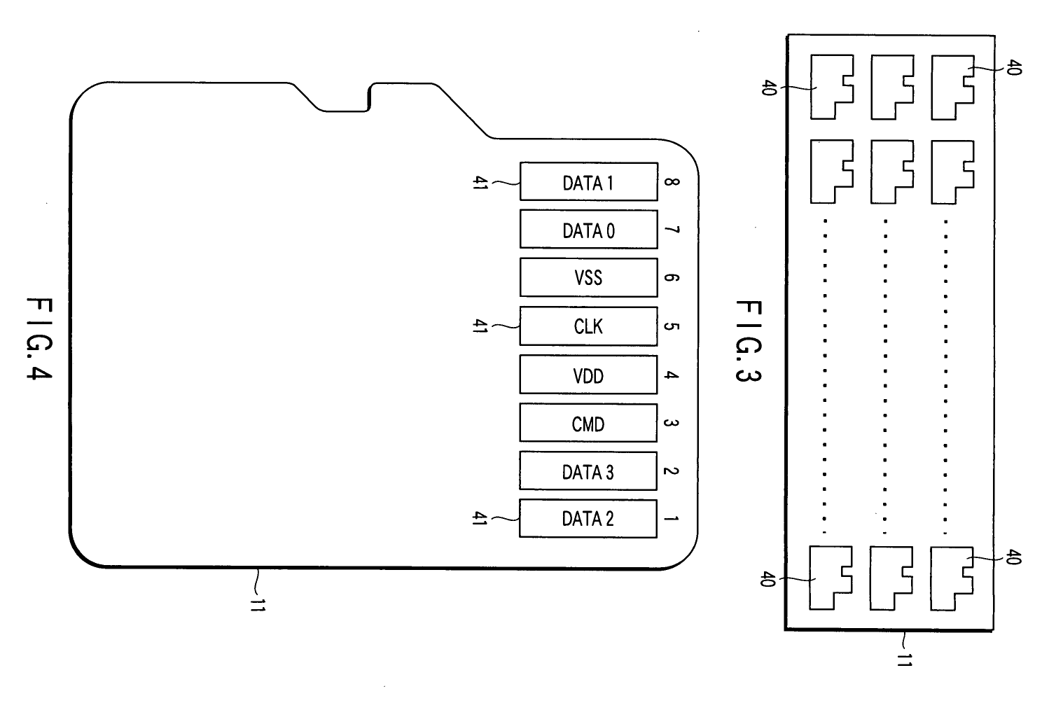

A board having a shape such as the one shown in FIG. 2 is formed as follows. As shown in a plan view of FIG. 3, on a single large board 11, formation of a wiring pattern on a plurality of semiconductor memory cards, mounting of a plurality of memory chips, a bonding process by metal wires, and a resin molding process on a memory chip adhesion surface side are performed, and then, individual memory cards 40 are cut out by a water jet process or the like. Since the adhesion force between the board 11 and the molding resin 20 is increased upon cutting out the outer shape of the individual memory cards, the occurrence of a defect due to peeling of the molding resin 20 at a side surface of the board 11 can be prevented.

FIG. 4 is a plan view of a surface opposite to the chip-mounted surface of the board 11 of FIG. 1. For example, eight plane-shaped external connection terminals 41 are formed on the surface of the board 11. These eight external connection terminals 41 are electrically connected to the memory chip and the controller chip through the wiring lines formed on the board 11 and metal wires. Here, signals are assigned to the eight external connection terminals 41 as shown in FIG. 4, for example. The first external connection terminal is assigned to data 2 (DATA2), the second external connection terminal is assigned to data 3 (DATA3), the third external connection terminal is assigned to a command (CMD), the fourth external connection terminal is assigned to a power supply voltage (VDD), the fifth external connection terminal is assigned to a clock signal (CLK), the sixth external connection terminal is assigned to a ground voltage (VSS), the seventh external connection terminal is assigned to data 0 (DATA0), and the eighth external connection terminal is assigned to data 1 (DATA1).

The semiconductor memory card is fabricated so as to be mountable on a slot provided in various host apparatuses such as a personal computer. A host controller (not shown) provided to a host apparatus performs communication of various signals and data with the semiconductor memory card through the eight external connection terminals 41. For example, when data is written to the semiconductor memory card, the host controller sends, as a serial signal, a write command to the semiconductor memory card through the third external connection terminal (CMD). At this time, the semiconductor memory card captures the write command provided to the third external connection terminal (CMD) in response to a clock signal supplied to the fifth external connection terminal (CLK).

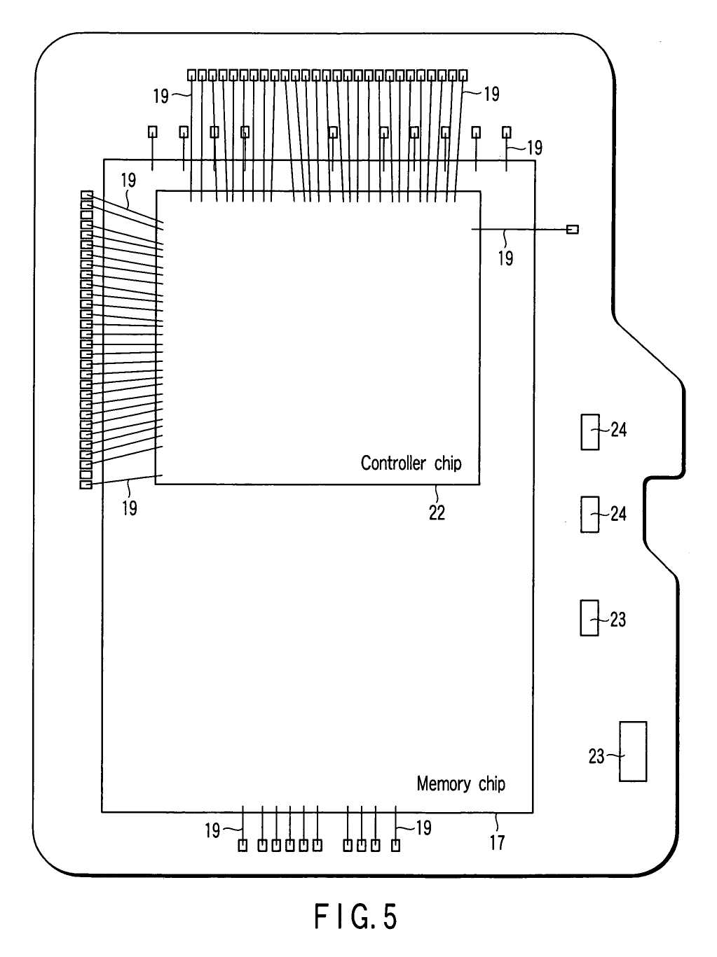

FIG. 5 is a plan view showing a state of connection between the chip mounted on the chip-mounted surface of the board 11 of FIG. 1 and the electrode pads on the chip and the board.

Here, a state is shown in which the memory chip and the controller chip which are stacked on top of each other are placed on the board 11. The memory chip 17 is a NAND memory chip with a memory capacity of, for example, 1 Gbit. A controller chip 22 is adhered to and mounted on the memory chip 17. Electrode pads on the memory chip 17 and the controller chip 22 are bonded to the electrode pads on the board 11 by metal wires 19. FIG. 5 shows a state in which not only the memory chip 17 and the controller chip 22 but also chip components, such as chip capacitors 23 and chip resistors 24, are electrically connected to the electrode pads on the board 11.

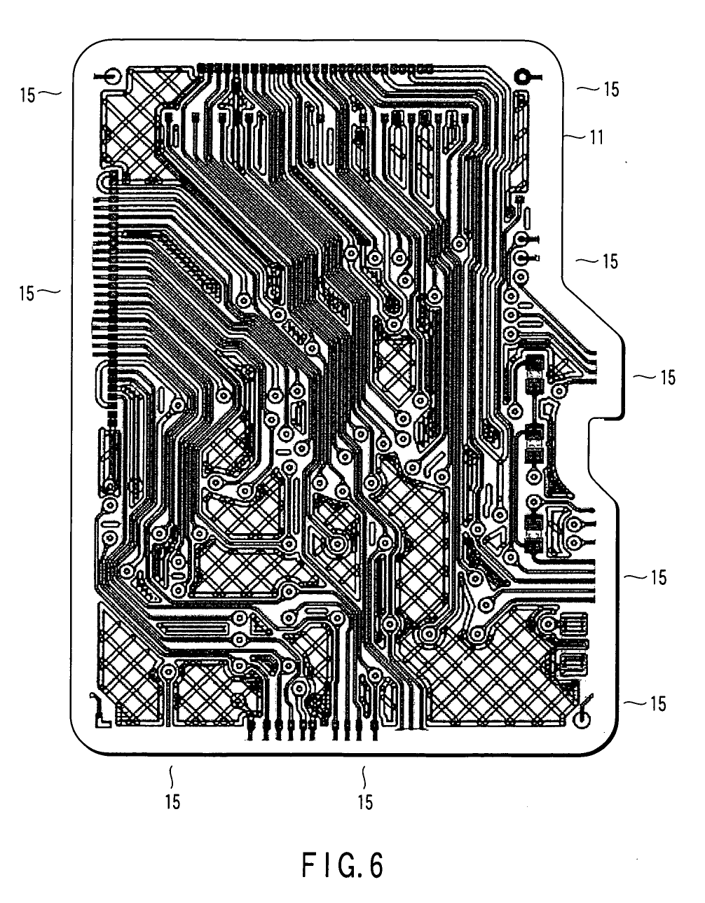

FIG. 6 is a plan view showing a specific example of the electrode pads and wiring pattern formed on the chip-mounted surface of the board 11 of FIG. 1. As described using FIG. 3, semiconductor memory cards are fabricated by performing, on a single large board, formation of a wiring pattern on a plurality of semiconductor memory cards, mounting of a plurality of memory chips, a bonding process by metal wires, and a resin molding process on a memory chip adhesion surface side, and then, individually cutting out the semiconductor memory cards by a water jet process or the like. The wiring pattern is formed by forming a film of a metal such as Cu, on the entire surface of an insulation board, performing plating on the Cu in a desired pattern shape and then performing etching. Upon performing plating on the Cu, plating is not performed on portions of Cu which are present in regions corresponding to the openings 15 of FIG. 1 in the outer periphery of the board 11 that are not coated with the solder resist 14, whereby a wiring pattern is not formed in these regions in a subsequent etching process. That is, this makes it possible to prevent an end of the wiring pattern from being exposed to the outside of the semiconductor memory card. This prevents the occurrence of corrosion or the like caused by the wiring pattern being exposed to outside air.

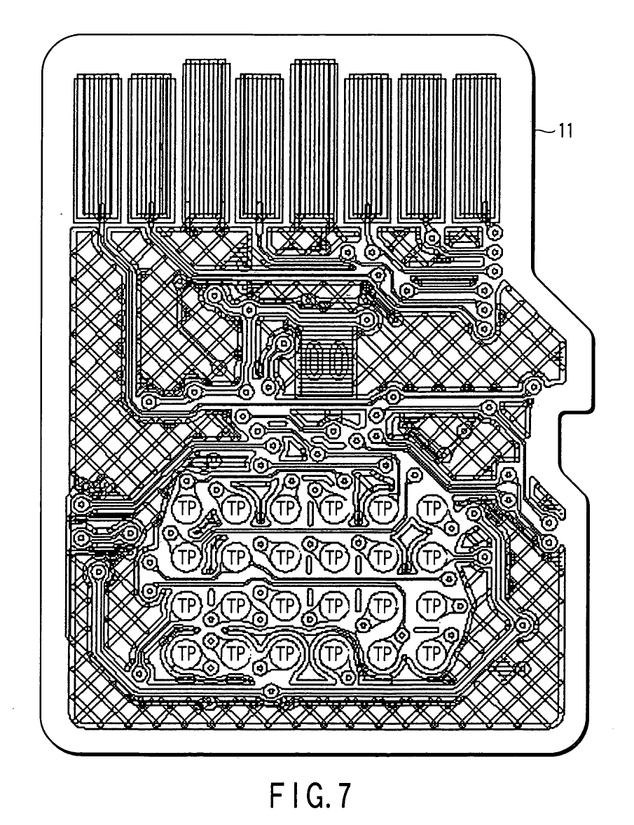

FIG. 7 is a plan view showing a specific example of the wiring pattern formed on the chip unmounted surface of the board 11 of FIG. 1. Note that FIG. 7 shows, unlike FIG. 4, a wiring pattern as viewed from the chip-mounted surface side of the board 11. Here, eight rectangular wiring portions at an upper part correspond to the external connection terminals 41 of FIG. 4. Portions indicated by “TP” at a lower part represent testing pads and are sealed with tape or the like upon actual use.

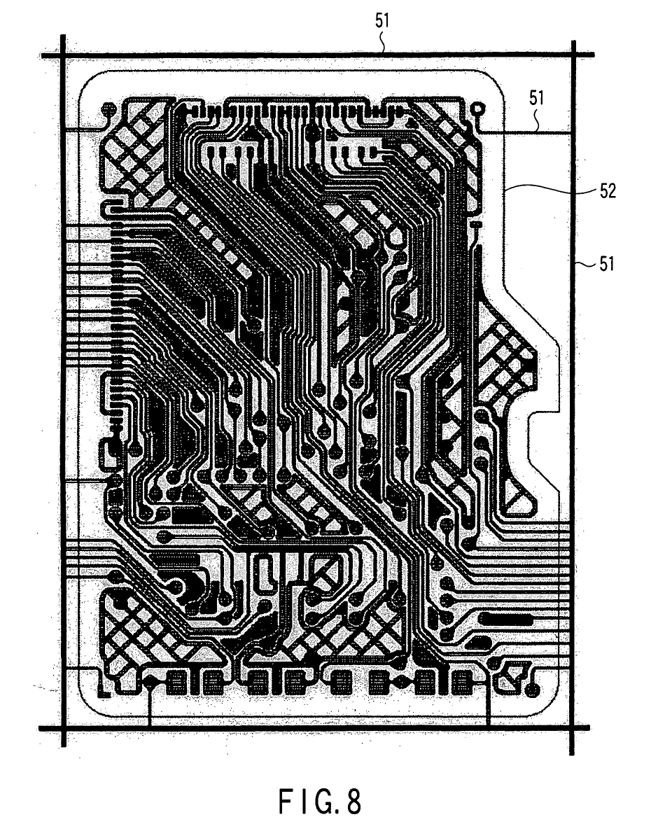

In the case where electrolytic plating is performed on the Cu film formed on the board 11, a potential needs to be provided to the Cu film. Therefore, as shown in a plan view of FIG. 8, on a board before cut out individually, a wiring line, in particular, a plating feeder line 51 used to provide a potential to electrode pads that require plating, is formed around the memory card. After electrolytic plating is performed and mounting of a semiconductor chip, bonding by metal wires, and a resin molding are performed, memory cards are individually cut out along outer shape lines of the boards 11. FIG. 8 is a plan view showing a specific example of the electrode pads and wiring pattern formed on a board before cut out, and an outer shape line of the board after cut out is indicated by reference numeral 52. Upon cutting out, the plating feeder line 51 is cut at a point of the outer shape line 52, and thus, an end face of the plating feeder line 51 is exposed at a side surface of a product after completion. When the end face of the plating feeder line 51 is exposed at the side surface of the product, the product becomes susceptible to noise from outside sources and static electricity, causing a memory chip malfunction and data corruption. Hence, it is not desirable to form the plating feeder line 51.

Now, description will be given to a method in which plating is performed without forming a plating feeder line so as to prevent an end face of the plating feeder line from being exposed at a side surface of a product.

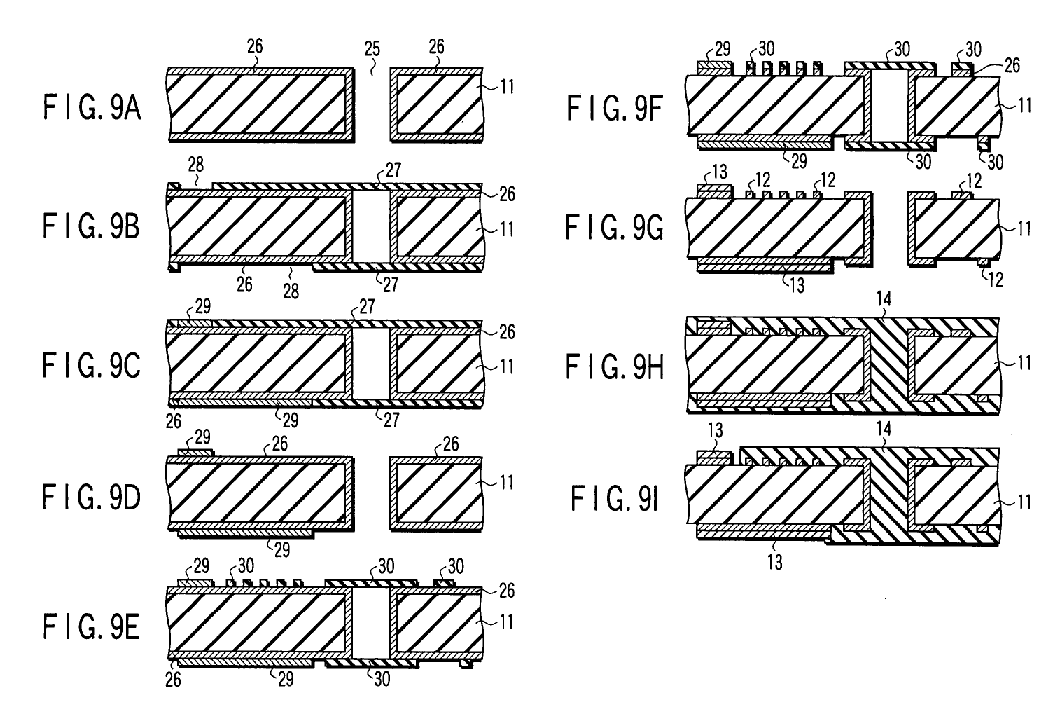

FIGS. 9A to 9I are cross-sectional views showing, in order of steps, a method of fabricating a semiconductor memory card, according to a second embodiment of the present invention. In this case, as shown in FIG. 3, a plurality of semiconductor memory cards are formed on a single large board, and then, the cards are separated individually.

First, as shown in FIG. 9A, a through-hole 25 is opened in a board 11, and subsequently, Cu plating is performed, whereby a metal thin film 26 made of Cu is formed on both surfaces of the board 11 including an inner surface of the through-hole 25.

Then, as shown in FIG. 9B, both surfaces of the board 11 are subjected to masking using dry films 27 and then to exposure and development, whereby openings 28 are provided in portions of the dry films 27 that require plating.

As shown in FIG. 9C, electrolytic Au plating is performed to form Au films 29 on portions of the metal thin films 26 where the openings 28 in the dry films 27 are provided. Upon the plating, an Au film 29 is not formed on a portion of the metal thin film 26 that corresponds to a conventional plating feeder line. After Au plating, the dry films 27 are removed as shown in FIG. 9D.

Subsequently, as shown in FIG. 9E, a mask layer 30 having a desired wiring pattern is formed on the metal thin films 26 on both surfaces of the board. Then, as shown in FIG. 9F, the metal thin films 26 on both surfaces of the board are selectively etched by using the mask layers 30. Upon the etching, a portion of the metal thin film 26 that corresponds to a periphery of each card is removed. More specifically, the metal thin films 26 are selectively etched such that when the cards are separated individually, the metal thin films 26 are not exposed from the peripheries of the cards. Thereafter, the mask layers 30 are removed as shown in FIG. 9G. By this process, a plurality of wiring lines 12 made of Cu and electrode pads 13 each having an Au film formed on a surface thereof is formed on both surfaces of the board 11.

Thereafter, as shown in FIG. 9H, solder resist 14 is formed by printing on both surfaces of the board 11. Then, as shown in FIG. 9I, portions of the solder resist 14 where part of an outer periphery of the board 11 and the electrode pads 13 are present are removed. Subsequently, a semiconductor chip is mounted on the board 11 and bonding is performed by metal wires, and then, a resin molding process is performed, and further, memory cards are individually cut out.

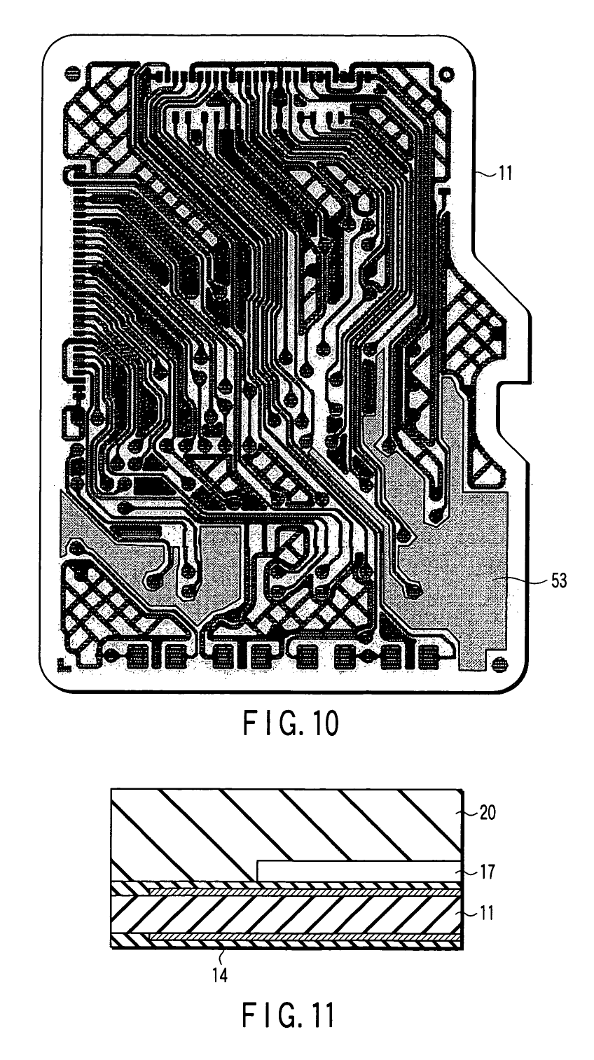

FIG. 10 is a plan view showing an example of wiring lines on a semiconductor chip unmounted surface of a semiconductor memory card fabricated by the aforementioned method. FIG. 11 is a partial cross-sectional view of a completed semiconductor memory card. Note that parts in FIG. 11 corresponding to those in FIG. 1 are denoted by the same reference numerals, and the description thereof is omitted.

According to the aforementioned method, a plating feeder line does not need to be formed around a memory card, and therefore, an end face of a plating feeder line (part of wiring lines) is prevented from being exposed at a side surface of a product. As a result, the product is made less susceptible to noise from outside sources and static electricity, making it possible to prevent a memory chip malfunction and data corruption.

Furthermore, since a plating feeder line does not need to be formed on a board, a region where wiring lines can be formed is increased, and, thus the wiring line length and the wiring line width can be increased, achieving optimization of the routing of wiring lines. Alternatively, by disposing a GND plane 53 or the like in an empty space on the board 11 as shown in FIG. 10, an advantage in terms of electrical characteristics is also provided.

Note that although the above describes the case in which Au films 29 are formed by electrolytic plating on metal thin films 26 made of Cu, various other plated films, e.g., Ni-Au films, may be formed in addition to Au films.

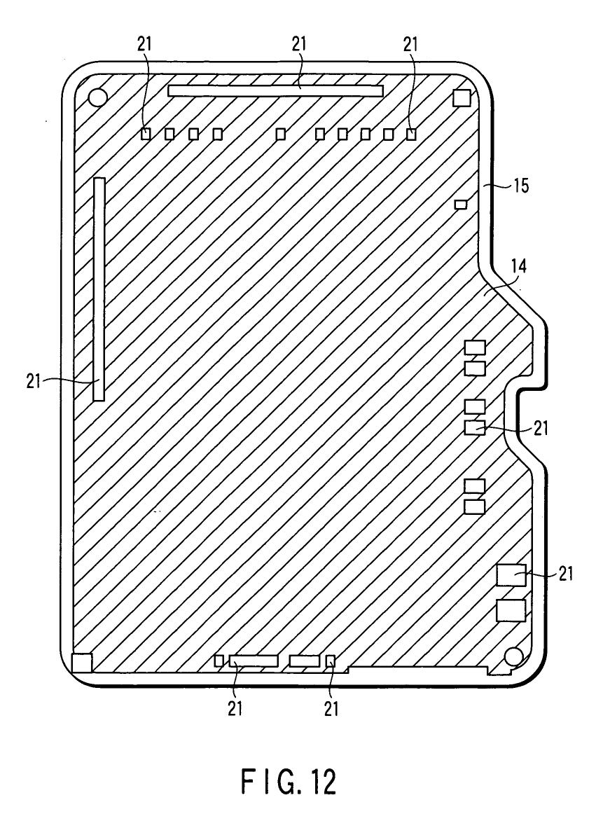

FIG. 12 is a plan view of a board 11 for use in a semiconductor memory card according to a third embodiment of the present invention. In a semiconductor memory card of the first embodiment, the case is described in which the openings 15 that are not coated with the solder resist 14 are provided in part of the outer periphery of the board 11.

On the other hand, in a memory card of the third embodiment, an opening 15 that is not coated with solder resist 14 is provided in a continuous region of an outer periphery of the board 11.

Such a configuration further increases the adhesion force between a board 11 and a molding resin 20, making it possible to prevent the occurrence of a defect due to peeling of the molding resin 20 at a side surface of the board 11.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory card which is usable mounted on a host apparatus, the semiconductor memory card comprising:
a wiring board having a first surface and a second surface which face each other, and having a plurality of external connection terminals and a plurality of wiring lines formed on the first surface;
a protective film formed on the second surface of the wiring board and having an opening in at least part of an outer periphery of the wiring board;
a memory chip mounted on the second surface of the wiring board; and
a resin film which composes a package of the semiconductor memory card by sealing a side of the second surface of the wiring board to cover the protective film and the memory chip.

2. The semiconductor memory card according to claim 1, wherein the opening in the protective film is provided in a continuous region of the outer periphery of the wiring board.

3. The semiconductor memory card according to claim 1, wherein the resin film is in contact with the wiring board through the opening in the protective film.

4. The semiconductor memory card according to claim 1, wherein the protective film is solder resist.

5. The semiconductor memory card according to claim 1, wherein end faces of the wiring lines are not exposed from an end of the wiring board.

6. The semiconductor memory card according to claim 1, wherein said plurality of external connection terminals include data input and output terminals, a command input terminal, a power supply voltage terminal, a clock signal input terminal, and a ground voltage terminal.

7. The semiconductor memory card according to claim 1, wherein the wiring board has a plurality of first electrode pads on the second surface, and the memory chip has a plurality of second electrode pads on a surface thereof.

8. The semiconductor memory card according to claim 7, further comprising:
a plurality of metal wires which electrically connect said plurality of first electrode pads to said plurality of second electrode pads.

9. The semiconductor memory card according to claim 1, further comprising:
a controller chip mounted on the memory chip.

10. A semiconductor memory card which is usable mounted on a host apparatus, the semiconductor memory card comprising:
a wiring board having a first surface and a second surface which face each other, and having a plurality of external connection terminals and a plurality of wiring lines formed on the first surface, plated films being formed on surfaces of said plurality of wiring lines, the plated films being formed by electrolytic plating, and end faces of the wiring lines being not exposed from an end of the wiring board;
a protective film formed on the second surface of the wiring board;
a memory chip mounted on the second surface of the wiring board; and
a resin film which composes a package of the semiconductor memory card by sealing a side of the second surface of the wiring board to cover the protective film and the memory chip.

11. The semiconductor memory card according to claim 10, wherein the opening in the protective film is provided in a continuous region of the outer periphery of the wiring board.

12. The semiconductor memory card according to claim 10, wherein the resin film is in contact with the wiring board through the opening in the protective film.

13. The semiconductor memory card according to claim 10, wherein the protective film is solder resist.

14. The semiconductor memory card according to claim 10, wherein the protective film has an opening in at least part of an outer periphery of the wiring board.

15. The semiconductor memory card according to claim 10, wherein said plurality of external connection terminals include data input and output terminals, a command input terminal, a power supply voltage terminal, a clock signal input terminal, and a ground voltage terminal.

16. The semiconductor memory card according to claim 10, wherein the wiring board has a plurality of first electrode pads on the second surface, and the memory chip has a plurality of second electrode pads on a surface thereof.

17. The semiconductor memory card according to claim 16, further comprising:
a plurality of metal wires which electrically connect said plurality of first electrode pads to said plurality of second electrode pads.

18. The semiconductor memory card according to claim 10, further comprising:
a controller chip mounted on the memory chip.

19. A method of fabricating a semiconductor memory card, comprising:
forming a metal thin film on both surfaces of an insulation board;
performing masking on both surfaces of the board by using dry films and then performing an exposure and development process, whereby openings are provided in selected portions of the dry films;
performing electrolytic plating to form plated films on portions of the metal thin films where the openings in the dry films are provided;
removing the dry films and then forming a mask layer having a desired wiring pattern on the metal thin films on both surfaces of the board;
selectively etching the metal thin films on both surfaces of the board by using the mask layers, and removing a portion of the metal thin film which corresponds to a periphery of a card and forming a plurality of wiring lines made of the metal thin films and a plurality of electrode pads made of the metal thin films and the plated films; and
forming solder resist on both surfaces of the board.

20. The method of fabricating a semiconductor memory card according to claim 19, wherein the metal thin films are Cu films.
